(19) United States
(12) Patent Application Publication
(10) Pub. No.: US 2025/0309801 A1
(43) Pub. Date: Oct. 2, 2025

(54) AUTOMATICALLY TUNING A POWER MANAGEMENT SYSTEM

(71) Applicant: LO AND HO PTY LTD, Arundel (AU)

(72) Inventor: Bruce LOXTON, Arundel (AU)

(73) Assignee: LO AND HO PTY LTD, Arundel (AU)

(21) Appl. No.: 19/118,322

(22) PCT Filed: Sep. 23, 2023
(86) PCT No.: PCT/AU2023/050926

§ 371 Date: Apr. 3, 2025

(30) Foreign Application Priority Data
Sep. 24, 2022 (AU) 2022902768

(51) Int. Cl. H02P 9/04; H02P 9/02; H02P 101/35; H02P 101/45

(52) U.S. Cl. CPC H02P 9/04; H02P 9/02; H02P 2101/35; H02P 2101/45

(57) ABSTRACT

The invention comprises automatically tuning a power management system (1000) adapted for use with a vehicle or marine electrical power system (100) powered by an internal combustion engine (105) and an alternator (110) driven by the internal combustion engine (105). A control module (220) of the power management system (1000) operates to determine maximum current limits able to be drawn from the alternator (110) by the control module for a predetermined alternator voltage setpoint at discrete engine operating speeds including an idle speed and at least one operating speed above idle speed, and generating a control strategy for controlling the current drawn from the alternator (105) at a prevailing engine speed using the determined maximum current limits and an error signal based upon the difference between the alternator voltage and the predetermined alternator voltage setpoint.

### TECHNICAL FIELD

The present invention relates to power management systems for use in vehicles and marine craft powered by internal combustion engines driving an alternator.

### BACKGROUND OF THE INVENTION

Vehicles and marine craft powered by an internal combustion engine use an alternator driven as an accessory to the engine to supply on-board electrical power systems. The alternator recharges the starter battery, and in the case of a passenger vehicle supplies power for the engine control unit (ECU), lights and many critical subsystems for steering, braking and so on.

There is however increasing demand for installing power-hungry electrical accessories for recreational and commercial applications. As an example, recreational vehicles may desirably include an induction cooktop, refrigeration, air conditioning and instant hot water systems. The demand presented by such accessories would overwhelm the capacity of a starter battery and a voltage-regulated alternator, requiring an intervening power system to manage power supply and demand.

Power management systems for non-factory accessories are based upon DC-DC converters and additional battery storage to meet load peaks, and also recharge battery storage. Integrating such power systems with factory power systems is a challenge and commercially available systems have various limitations.

Furthermore, in modern vehicles a power management system must accommodate factory features such as smart alternators, regenerative braking systems, engine stop-start features and power intensive systems such as electronic steering. These features are controlled by the vehicle's ECU and an integral part of the vehicle design that must be accommodated.

One challenge for existing power management systems which is not well addressed is efficiently extracting surplus alternator capacity reliably across the RPM band from an alternator.

An objective of the present invention is to at least attempt to address one or more of these and other limitations of existing solutions.

### SUMMARY OF INVENTION

The inventive concept arises from the insight that operating a power management system for an engine-driven alternator desirably involves a strategy of self-tuning by learning the power parameters of the attached alternator under different engine operating conditions.

This is achieved by determining a distribution of maximum current limit points across different engine speed conditions, and delimiting operating ranges in which different control parameters or strategies are implemented to control the current demanded by the power management system from the alternator.

This approach specifically avoids reading the actual engine speed as a basis for implementing a control strategy.

Advantageously, each delimited operating range adopts a proportional-integral-differential (PID) control scheme, in which the specific PID parameters for each operating range are selected to best suit that particular operating range. The voltage-characteristic varies in each delimited operating range, and hence it is preferred to adopt a different balance of PID parameters to achieve a desired control response. Different sets of PID parameters can optionally be used within an operating range, conditional upon whether engine speed is increasing or decreasing.

The primary measured variables are alternator voltage and a reference voltage delivered to the power management system as an input voltage and characterised as a predetermined alternator voltage setpoint. The controlled variable is load current drawn by the power management system from the alternator.

The alternator voltage is measured at the alternator, rather than at the power management system at the terminal end of the cable connecting to the alternator. Vehicle installations vary in terms of placement of the power management system and distance from the engine bay. Owing to unknown cable distance and a wide range of current levels drawn from the alternator there exists a variable and undefined voltage difference between the actual alternator voltage. Accordingly, a more reliable control strategy can be achieved by reading the alternator voltage locally at the alternator.

The present invention comprises in one embodiment a method of tuning a power management system adapted for use with a vehicle electrical power system powered by an internal combustion engine and an alternator driven by the internal combustion engine, the power management system comprising a power control system comprising a DC-DC converter for converting power between the vehicle electrical power system and a target battery storage, and a control module controlling the DC-DC converter.

The method comprises steps performed by the control module of determining maximum current limits able to be drawn from the alternator under direction from the power control module for a predetermined alternator voltage setpoint at different engine operating speeds, preferable an idle speed and one or more operating speeds greater than idle speed, and generating a control strategy using the determined maximum current limits based upon controlling the current drawn from the alternator using an error signal based upon the difference between the alternator voltage (preferably measured accurately at the alternator) and the predetermined alternator voltage setpoint.

The DC-DC converter is preferably bidirectional to enable power to be returned to the vehicle if and when required. The DC-DC converter can preferably operate in buck-boost mode as a higher output voltage, such as 48V is more efficient than 12V or 24V output at the higher power levels, and hence amperage levels, delivered from the vehicle.

The present invention further comprises a control module of the type described and adapted for performing the steps described, and a power management system comprising such a control module.

The power management system according to embodiments of the present invention addresses a desirable objective, namely optimising the electrical power drawn from an alternator as a vehicle operates at varying prevailing engine speeds across its operating band, without exceeding the capability of the alternator.

Attempting to extract more current than an alternator is capable of delivering at a particular engine speed leads to voltage collapse, and often alternator overheating or damage owing to excessive current and heat.

Preferred embodiments of the present invention are suitable for use with a range of engine applications and alternator configurations. As well as typically vehicle engines, the DC-DC converter controller system is also suitable marine engines, which have lower output engines and higher output alternators compared to typical vehicle configurations.

Optional alternator temperature protection can be used. While overheating is unlikely for vehicle applications where alternator output peaks under cruising RPM conditions, this is a safeguard that may be desirable in certain applications.

### BRIEF DESCRIPTION OF DRAWINGS

FIG. 1 depicts in schematic form a power management system according to a preferred embodiments of the present invention when installed in a vehicle.

FIG. 2 depicts in schematic form the power management system of FIG. 1, in further detail.

FIG. 3 is an illustrative tuning map used in connection with the procedure of FIG. 4.

FIG. 4 is a flowchart of the procedure for operating the power control system featured in FIG. 1, and show in further detail in FIG. 2, in overview.

FIG. 5 is a flowchart (presented as FIG. 5A and FIG. 5B) of a procedure for automated tuning of the power control system of FIG. 2, preparatory to operation according to FIG. 2.

FIG. 6 is a graph depicting points of maximum output current limit captured at discrete engine operating speeds during an ‘auto-tuning’ procedure.

FIG. 7 is a graph depicting points of maximum output current limit captured at discrete engine operating speeds during a ‘fine-tuning’ procedure.

### DETAILED DESCRIPTION OF PREFERRED EMBODIMENTS

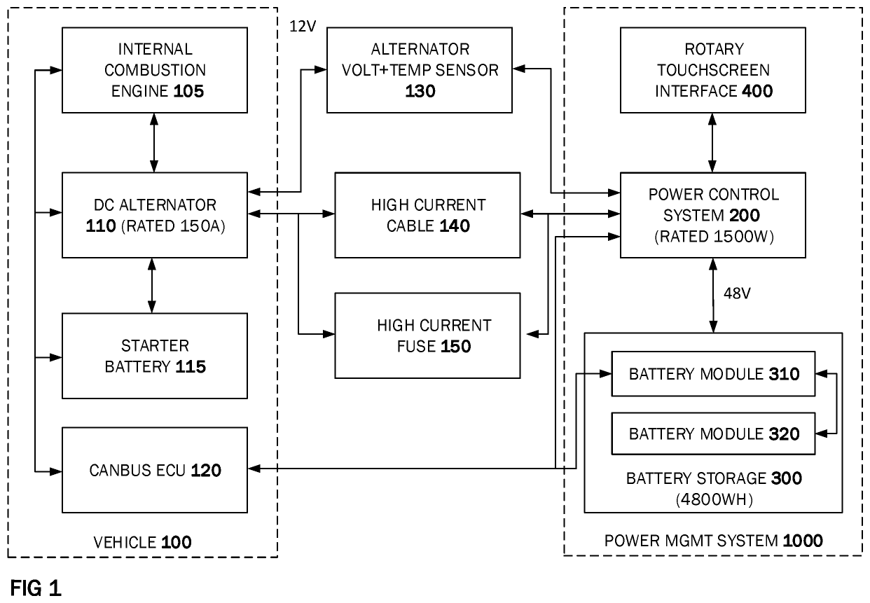

FIG. 1 depicts in schematic form components of a power management system 1000 when installed on a vehicle 100.

Vehicle 100 comprises an internal combustion engine 105, DC alternator 110, starter battery 115 and CAN Bus ECU 120. CAN Bus (Controller Area Network bus) provides a messaging-based protocol standard for vehicle microcontrollers to communicate with each other, permitting access to configuration, diagnostics and data logging. The CAN Bus-enabled ECU 120 can thus communicate to subsystems and components of the vehicle 100 through respective microcontrollers. As is typical, the CAN Bus ECU 120 is connected to the internal combustion engine 105, the alternator 110, and starter battery 115. Alternator 110, as is familiar, is belt driven by the engine 105 and generates electrical power from the rotary motion of its rotor around a stator. A rectifier and regulator delivers a DC current at a nominal 12V, which powers various vehicle accessories (ECU 120, as well as other electronic accessories and subsystems (not shown)).

ECU 120 also connects to the power management system 1000, more specifically the power control system 200 and also the battery modules 310, 320.

Power management system 1000 when installed on the vehicle 100 extracts and manages power from the vehicle, more specifically the alternator 110. Power management system 1000 comprises a power control system 200 which connects to battery storage 300, and is operated though a rotary touchscreen interface 400.

The touchscreen interface 400 is a ruggedised device that features a small circular touchscreen surrounded by a knurled rotary switch which indexes multiple selections (for example, 32). The touchscreen interface is preferably supplied from the range of touch encoders supplied by Grayhill, Inc of Illinois. The touchscreen interface 400 connects to the power control system via a serial bus such as USB 2.0.

Battery storage 300 comprises in the example illustrated two lithium battery modules 310, 320 of matching capacity of 2400 Wh for a combined total of 4800 Wh, which is generally matched to the capacity of 150 A for alternator 110 and the 1500 W capacity of the power control system 200.

Power control system 200 receives power from the vehicle at a nominal 12V (low side) and directs power to the battery storage 300 at a nominal 48V (high side). Battery storage 300 in turns supplies accessories (not shown), which draw power from battery storage 300. The power control system 200 when required withdraws power from battery storage 300 for return to vehicle 100.

Power control system 200 draws (and returns) power from the vehicle 100, more particularly the alternator 110 and starter battery 120 via high current cable 140. As indicated, high current cable is rated in excess of 150 A to match alternator 110. An alternator sensor 130 for voltage and temperature is connected to the alternator 110 wired back to the power control system 200, and a high current fuse 150 is wired to around high current cable 140 to trip in the event of excess current to avoid drawing excessive current which would damage alternator 110.

The power control system 200 is also connected to the ECU 120, and communicates over CAN Bus, though communication via CAN Bus is not essential to the techniques described herein.

The voltage received from the alternator 110 at the power control system 200 over high current cable 140 will be less than the alternator voltage measured by alternator sensor 130 a small and variable amount owing to the installation length of the cable 140, and the current the cable 140 is drawing.

The cable 140 may be 3 m-5 m long depending on where the power management system 1000 is installed on the vehicle 100. Thus the voltage difference across high current cable 140 may approach up to say 0.3V. A more reliable value can be read by the power control system 200 by operation of sensor 130 connected to the control module 220, or optionally via the ECU 120.

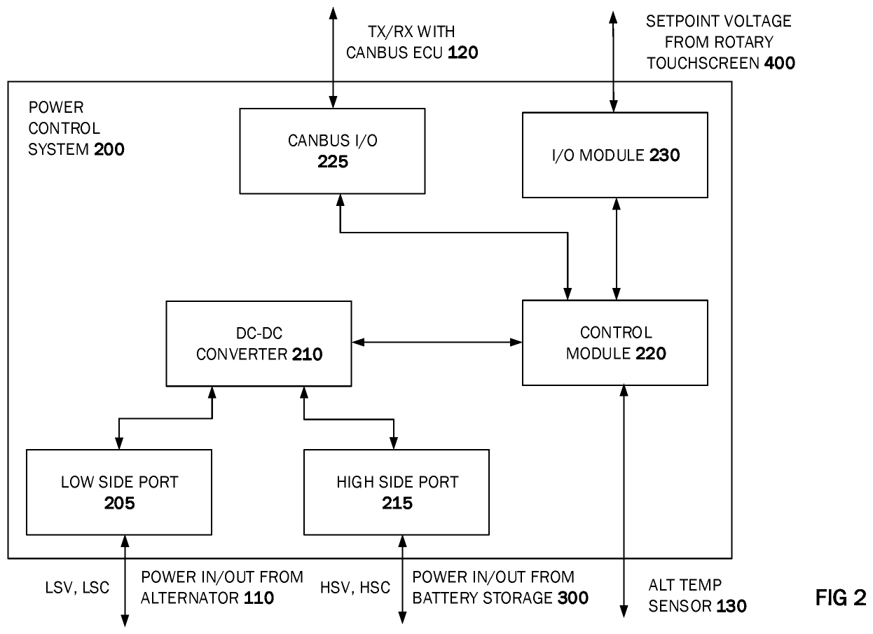

FIG. 2 depicts in schematic form the components of the power control system 200.

Power control system 200 comprises power ports 205, 215, namely low side port 205 at a nominal 12V and high side port 215 at a nominal 48V. Low side port 205 draws power from alternator 110, and high side port 215 delivers power to battery storage 300—through DC-DC converter 210 which connects the power ports 205, 215. DC-DC converter 210 is bi-directional, and power may be directed to flow in the opposite direction if required, namely from battery storage 300.

The DC-DC converter 210 is controlled by a control module 220. Control module 220 is connected to ECU 120 through a CAN Bus I/O module 225 and with touchscreen interface 400 via I/O module 230. It should be noted that the methods and systems described herein are not reliant upon CAN Bus connectivity however.

Control module 220 comprises a general-purpose microprocessor platform or modular control unit, such as selected from the range available commercially from NXP Semiconductors NV of the Netherlands.

The converter 220 is preferably bi-directional and may be supplied from the range supplied by Calex Manufacturing Co, Inc of California.

Converter 220 operates as described above under direction of the control module 220, and regulates the average current flowing between the low side port 205 and high side port 215 in a direction specified by a DIR signal received from the control module 220.

Converter 220 operates in constant current mode (CCM) or constant voltage mode (CVM). In the constant current mode, the low side current (LSC) is programmed and regulated regardless if the converter is in buck or boost mode.

The converter 220 may be unidirectional though is preferably bidirectional in terms of being capable of exchanging power in both directions as required, under direction of the control module 220. This may routinely occur following start of engine 105 of the vehicle 100 or otherwise when low side accessories (not shown) have depleted the starter battery 115.

Current direction in the converter 210 is reversed by the control module 220 reducing the LS current to zero, and changing the DIR signal to indicate an opposite current direction, and then increasing current flow in that reverse direction after a short time delay of the order of 30 milliseconds.

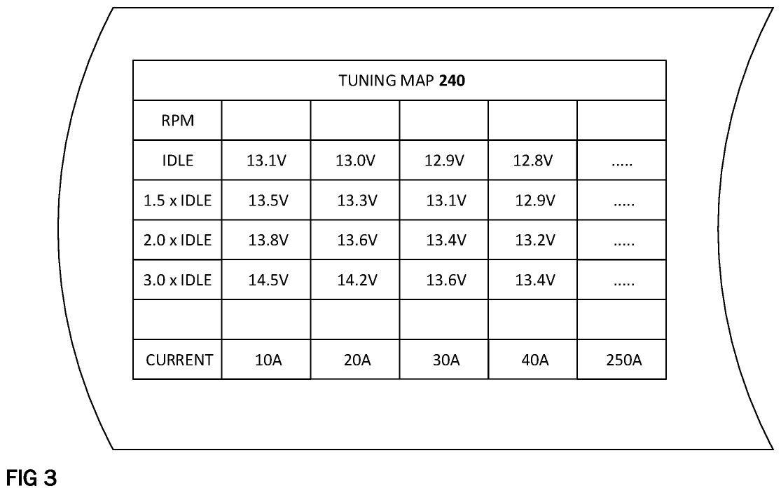

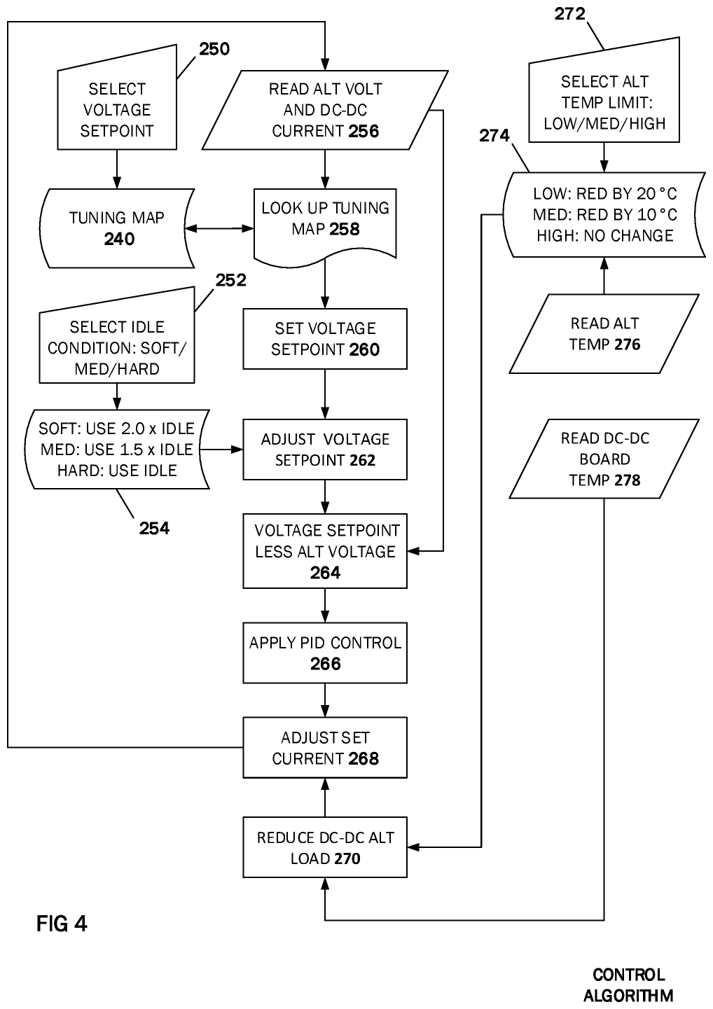

FIGS. 3 and 4 respectively depict a tuning map 240 and a flowchart procedure for operating the power management system 1000, which involves the tuning map 240.

Tuning map 240 of FIG. 3 depicts a (contracted and illustrative) table of alternator voltage values at various alternator current draws at a series of discrete engine operating points having different engine operating speeds. This characteristic will be vehicle specific as it depends upon the specific engines and alternator combinations.

The specific engine operating points are arbitrary, and may be selected as a matter of preference and suitability to application.

The tuning map 240 as depicted is a look up table of values that records alternator voltage-alternator current characteristics at operating points defined in this instance: (i) idle, (ii) 1.5× idle, (iii) 2.0× idle, (iv) 3.0× idle. Other operating points may be selected-such as specific engine RPM increments above idle, as well as other regimes.

At each successive operating point, the alternator voltage decreases with increasing alternator current, but will maintain a higher voltage for increasing levels of alternator current. At some point, at each operating point, a current draw is reached at which the alternator starts to collapse. Sustained elevated current draw can damage the alternator so hence it is desirable to determine a maximum current limit for a predetermined predetermined alternator voltage setpoint that is greater than the voltage at which the alternator can operate.

The alternator current characteristic against engine operating speed is not linear but instead is non-decreasing and demonstrates a characteristic convex profile. The rate of increase of output current decreases with increasing RPM between idle RPM and cruising RPM. The relationship between output current and RPM broadly presents as a logarithmically increasing function.

The output current at idle RPM (for example 600 RPM) is typically half that of the output current at cruise RPM (for example 2400 RPM).

The tuning map 240 thus defines a maximum current limit for a predetermined alternator voltage setpoint. As an example, assume a predetermined alternator setpoint of 12.8V. A typical vehicle can safely accommodate a sustained current draw that maintains alternator voltage above 12.5V.

Referring to the tuning map 240, the alternator can accommodate a current draw of 10A to 40A at an idle operating speed. When the engine speed is 1.5× idle, a higher alternator current can be supported before the alternator voltage decreases to 12.8V.

As evident in FIG. 4, an operator may select an idle condition of (i) soft, (ii) medium or (iii) hard. Hard setting draws current at the maximum current limit, at say 12.8V. The offset to a higher voltage for the medium setting and soft setting is automatically selected based upon the initial auto-tuning so that approximately half the power is extracted on a soft setting, and approximately three-quarters is extracted on medium setting.

Thus, hard setting may suit a stationary application with high power usage (for example, food service van), whereas medium or soft may be preferred when one can expect enough driving to more than recharge battery storage.

Turning more specifically to FIG. 4, an operator selects a voltage setpoint in step 250, using touchscreen interface 400. This operator flexibility is to accommodate different applications and operating conditions. A typical selection for a vehicle would be 12.8V, which for control purposes translates to 12.5V.

The operator selects the idle setting in step 252, also using rotary touchscreen interface 400—available selections are soft, medium, and hard, as discussed above and below in further detail. The control module 200 reads the prevailing alternator voltage and DC-DC current in step 256, and looks up the tuning map 240 in step 258.

The voltage setpoint is adjusted in step 260 in light of the retrieved tuning characteristic retrieved from the tuning map 240. The initial voltage setpoint can be adjusted in a range.

Also, the voltage setpoint is adjusted in step 262 in response to the selected idle condition as described above in connection with steps 252 and 254.

The adjusted voltage setpoint less the alternator voltage is calculated in step 264. This is an error signal, which is input to the PID control loop executing in the control module 220 in step 266, which results in an adjusted set current sent to the DC-DC converter 210. As the control strategy is reliant upon a control loop sensing a differential between the voltage setpoint and alternator voltage, it is preferred to measure alternator voltage at the alternator 110 rather than sensing this value from the control module 220, owing to the unknown difference between these values.

A reduction in DC-DC alternator load current is also determined in step 270, and is input to the process for determining the adjusted set current in step 266 described above. This occurs in the event of detected overheating. An operator selects an alternator temperature limit using touchscreen interface 400 in step 272. This may be set as low/medium/high according to operator selection. This selection is input to step 274, in which an alternator limit is reduced by 20° C. in the event of a low section, reduced by 10° C. in the event of a medium selection, and not reduced in the event of a high selection. Alternator temperature is read in step 278 using alternator temperature sensor 130, and this reading factored into step 274, by comparing the alternator temperature limit and the actual read alternator temperature. Also, the board temperature at the DC-DC converter 210 is read by the control module 220 in step 278 and compared with a board temperature limit.

The DC-DC alternator load is determined to be reduced by a certain amount in step 270 should the alternator temperature or board temperature in steps 274 and 278 are found to be excessive. This determination factors into the adjusted set current in 268 which is sent to the DC-DC converter 210.

Following step 268, the alternator voltage of the alternator 110 and DC-DC current at DC-DC converter 210 is read in step 256 again, in the wake of adjustment in step 268 and the described process above repeats during operation of vehicle 100.

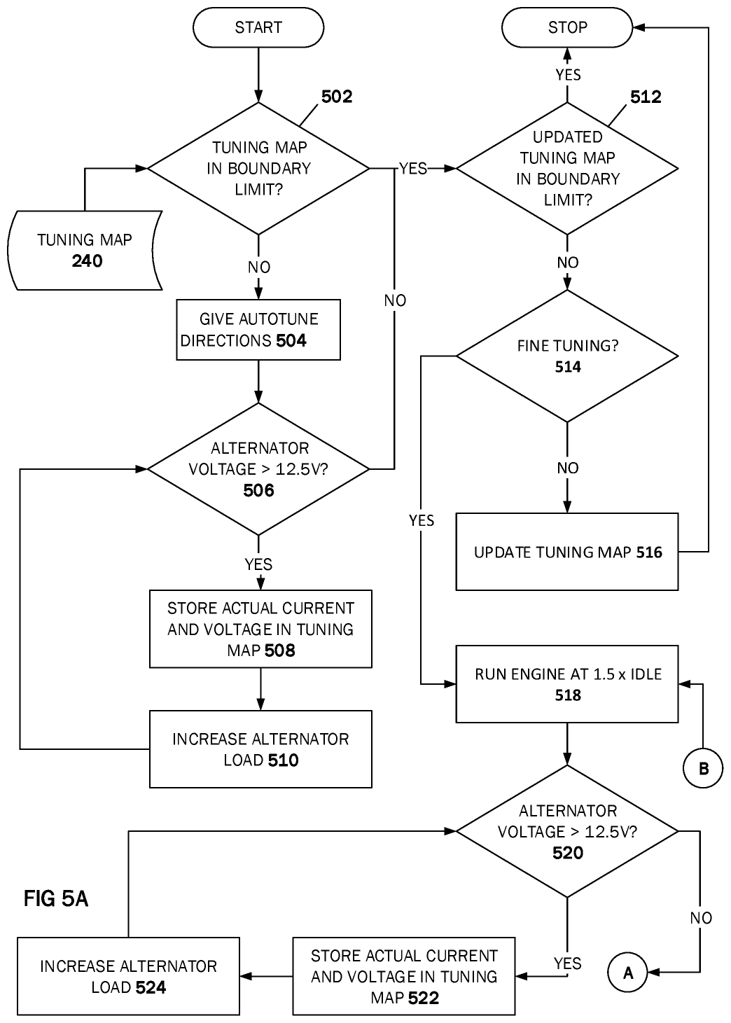

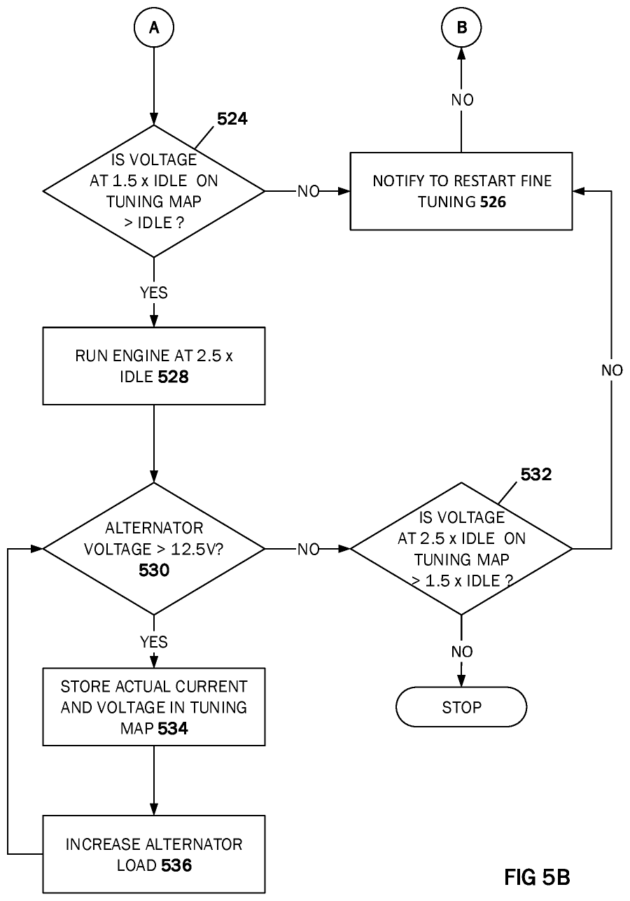

A tuning procedure is now described in connection with FIG. 5. The procedure starts as indicated in FIG. 5A. Tuning map 240 is read and a determination made to check if the tuning map 240 is in boundary limit in step 502.

If the result is NO, directions to activate an autotune procedure are given to the operator via touchscreen interface 400 in step 504. A check is made if the alternator voltage is greater than the voltage setpoint voltage, 12.5V in this example, in step 506. If YES, then the actual alternator current and alternator voltage is stored in the tuning map 240. The alternator load is increased by a certain increment, such as 10A, in step 510 and step 506 repeated as depicted, with steps 508 and 510 repeated as above until there is a NO result from step 506, that is alternator voltage is not greater than 12.5V.

Processing then passes to step 512 in which a check is made if the updated tuning map 240 is in boundary limit. If that is the case, processing stops as indicated. Otherwise if there is a NO result to the boundary limit question, the operator is offered the option of conducting fine tuning in step 514, through the touchscreen interface 400. If fine tuning is declined, the tuning map 240 is updated in step 516 and processing stops thereafter as depicted.

If fine tuning is selected in step 514, the operator is directed to operate the engine at 1.5 times idle speed in step 518. Again, a check is made in step 520 if the alternator voltage is greater than 12.5V. If so, the actual alternator current and alternator voltage is stored in tuning map 240 in step 522, and thereafter alternator load increased in step 524, for example, incrementing by 10A. Processing returns to step 520, and the loop iterates until alternator voltage is not greater than 12.5V.

A check is then made in step 524 (see FIG. 5B) as to whether or not alternator voltage at 1.5 times idle in tuning map 240 is greater than the alternator voltage at idle. If NO, which would be irregular, the control module 220 instructs the touchscreen interface 400 to restart the fine tuning procedure in step 526, with processing returning to step 518 (see FIG. 5A).

IF YES, fine tuning progresses by the operator running the engine 105 at 2.5 times idle in step 528, following prompt from touchscreen interface 400.

A check is made in step 530 as to whether or not alternator voltage is greater than 12.5V. If YES, actual alternator current and alternator voltage are stored in tuning map 240 in step 534. And alternator load is increased (for example, by 10A) in step 536, and then processing returns to step 530. This sequence repeats until alternator voltage is not greater than 12.5V.

A check is then made in step 532 as to whether or not alternator voltage at 2.5 times idle on tuning map 240 is greater than that at 1.5 times idle. If NO, processing stops with fine tuning completed. Otherwise if YES, processing returns to step 525 to restart fine tuning procedure as described above.

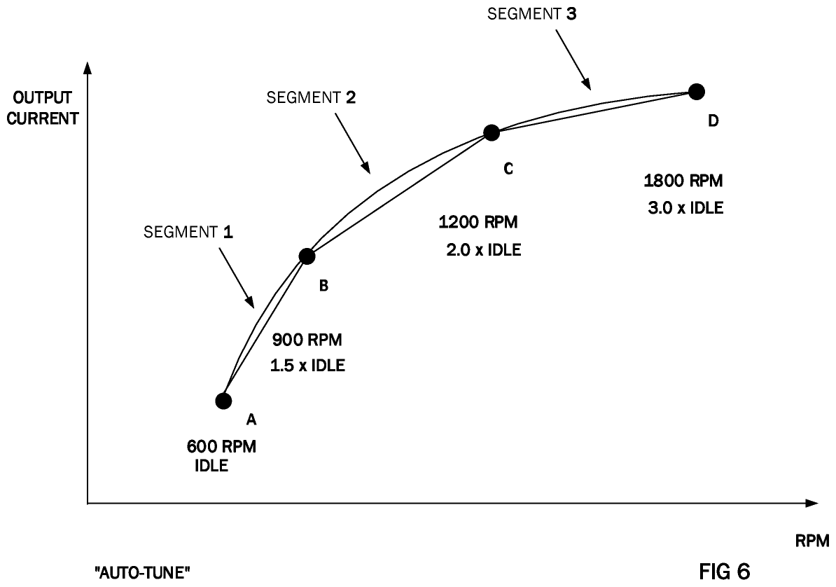

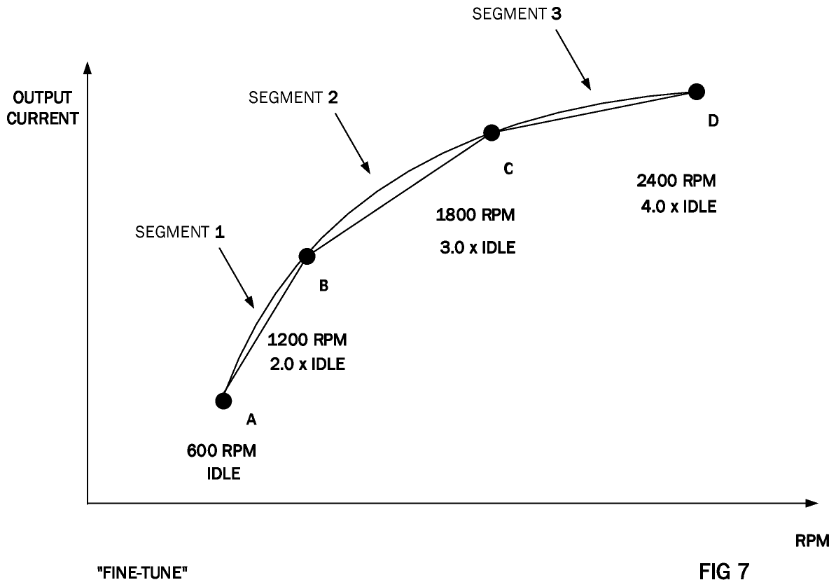

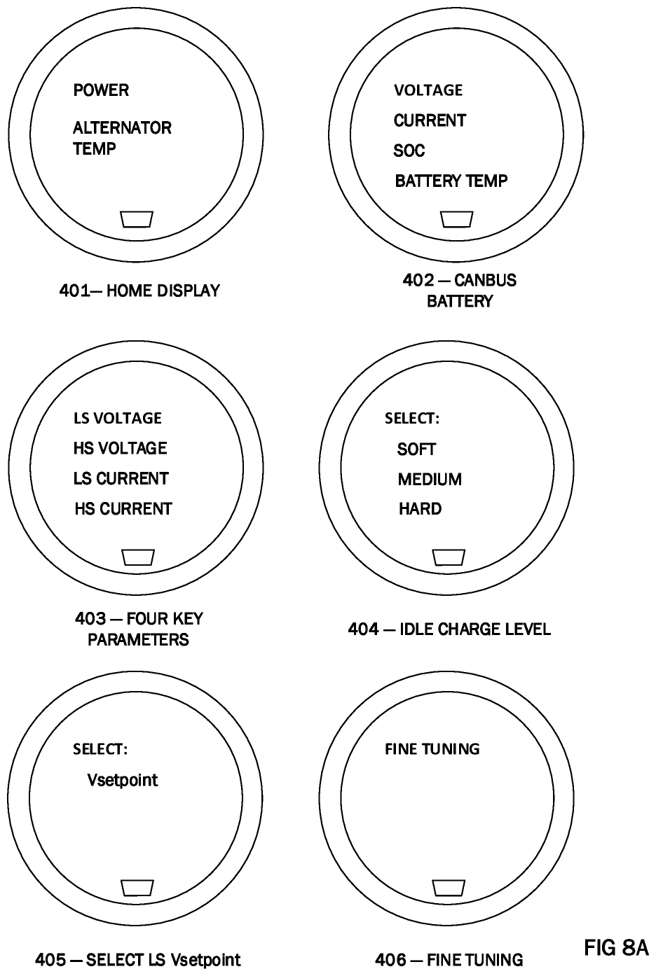

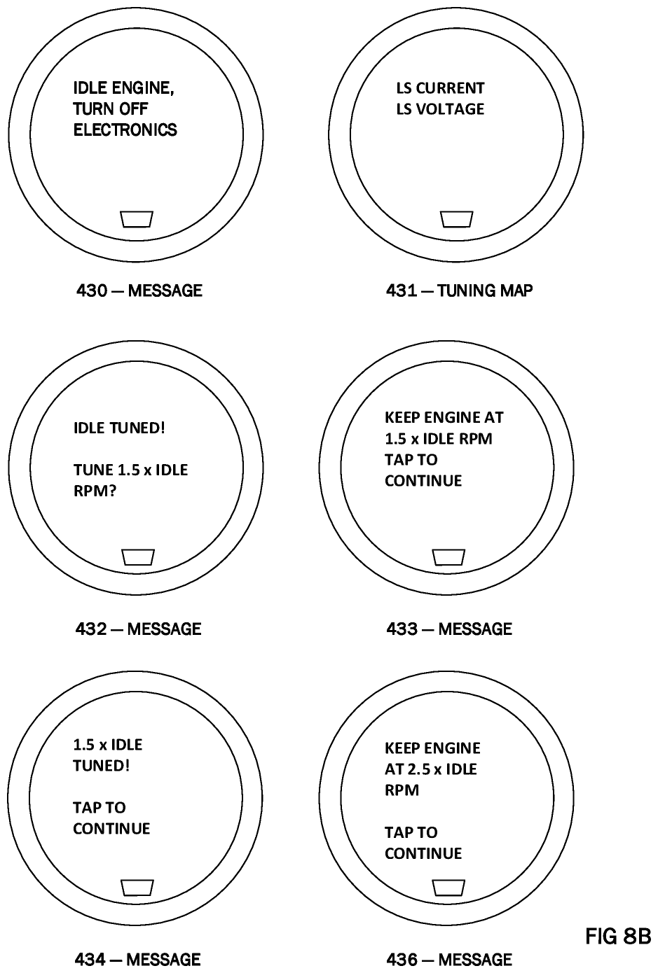

FIGS. 6 and 7 depict exemplary tuning curves for an auto tuning procedure (FIG. 6) and a fine tuning procedure (FIG. 7).

Both examples are characterised by discrete engine operating speeds for which alternator output current is measured for alternator output voltage, as recorded in tuning map 240. The auto tuning example depicts discrete engine operating speeds of (i) idle, (ii) 1.5× idle, (iii) 2.0× idle, and (iv) 3.0× idle. This matches the example tuning map 240. The fine tuning example depicts discrete engine operating speeds of (i) idle, (ii) 2.0× idle, (iii) 3.0× idle and (iv) 4.0× idle.

Both examples share four discrete engine operating speeds thus defining three discrete control ranges.

It will be noted that the example of FIG. 5 indicates discrete control ranges of (i) idle, (ii) 1.5× idle, and (iii) 2.5× idle. In this case, there are three discrete engine operating speeds and thus two discrete control ranges.

The number and placement of engine operating speeds for tuning purposes is largely arbitrary according to the needs of a particular application. The requirement is to segment the engine operating characteristic into two or more discrete control segments.

As described, using discrete multiples of idle speed is but one way to achieve this segmentation. Other strategies involve an additive increment to idle speed, or an indexed additive increment to idle speed. So, for example, a different approach would be segmenting engine operating speed by (i) idle, (ii) idle+200 RPM, (iii) idle+400 RPM, and (iv) idle+600 RPM. Or perhaps (i) idle, (ii) idle+100 RPM, (iii) idle+300 RPM, (iv) idle+900 RPM. There are many other possibilities that may be selected to meet requirements.

At the simplest level, the lower speed characteristic is different from the higher speed characteristic, with a more dynamic current output at lower speeds, and a more stable current output at higher speeds. Pragmatically, segmenting the engine operating range into two, three or four discrete control segments should suffice for most applications.

As can be appreciated, the rationale for discrete control ranges is that different control parameters (or indeed, different control strategies) are desirable for each control range. An example control strategy that can be applied across control ranges is simple PID control, but with different (P, I, D) parameters applying in each range. And additionally, one may select different (P, I, D) parameters dependent upon whether or not the output current is increasing or decreasing.

Lower control ranges will typically adopt higher P parameters for a quick response, and lower I and D parameters, and higher control ranges will typically adopt smaller P parameters, and higher I and D parameters, for example.

FIG. 8 depicts by way of illustration a selection of several screens of the rotary touchscreen interface 400 that can be selected by an operator by rotating the dial of the interface 400 to indexed position (FIG. 8A), or which appear following certain prompts in connection with the fine tuning procedure (FIG. 8B) as described above in connection with FIG. 5.

Referring in FIG. 8A, home display 401 indicates Power and Alternator temperature, CAN Bus Battery display 402 indicates battery voltage, battery current, battery state of charge, and battery temperature.

Four key parameters display 403 indicates low side voltage, high side voltage, low side current and high side current. Idle charge level display 404 permits the operator to select soft, medium or hard options as described in step 252 (see FIG. 4).

Voltage setpoint selection display 405 permits the operator to select the voltage setpoint as described in step 250 (see FIG. 4).

Fine tuning display 405 permits the operator to select an option of fine tuning as described in step 514 (see FIG. 5A).

Message display 430 directs the operator to idle the engine 105 and turn off electronics in the vehicle 100.

Tuning map display 431 indicates low side current and low side voltage between information message screens during the fine tuning process.

Message display 432 indicates to the operator that the idle is tuned, and prompts the operator to increase engine speed to 1.5× idle RPM as described in step 518 (see FIG. 5A). Message display 433 prompts the operator to keep the engine speed at 1.5× idle and confirm once finished. Message display 434 confirms that 1.5× idle is tuned.

Message display 436 prompts the operator to keep the engine at 2.5× idle, as described in step 525 (see FIG. 5B).

As will be appreciated the preferred embodiment and its variants as described and depicted herein may be varied within the scope of the present Invention.

1. A method of automatically tuning a power management system adapted for use with a vehicle or marine electrical power system powered by an internal combustion engine and an alternator driven by the internal combustion engine, the power management system comprising a power control system comprising a DC-DC converter for converting power from the electrical power system, and a control module controlling the DC-DC converter, the method comprising steps performed by the control module of:
determining maximum current limits able to be drawn from the alternator by the control module for a predetermined alternator voltage setpoint at discrete engine operating speeds, the discrete engine operating speeds including an idle speed and at least one operating speed above idle speed; and
generating a control strategy for controlling the current drawn from the alternator at a prevailing engine speed using the determined maximum current limits and an error signal based upon the difference between the alternator voltage and the predetermined alternator voltage setpoint.

2. The method of claim 1, wherein the control strategy is characterised by multiples operative modes that respectively draw differing levels of current from the alternator by varying the predetermined alternator voltage setpoint used in the control strategy.

3. The method of claim 1, wherein the selected engine operating speeds define discrete control ranges to which discrete control strategies are applied.

4. The method of claim 3, wherein the control strategy comprises a proportional-integral-derivative (PID) control strategy.

5. The method of claim 4, wherein the proportional-integral-derivative (PID) control strategy comprises respective sets of PID control parameters for the discrete control ranges.

6. The method of claim 5, wherein the sets of PID control parameters for the discrete control ranges are different depending upon if the current drawn from the alternator is increasing or decreasing.

7. The method of claim 1, wherein the DC-DC converter is bi-directional.

8. The method of claim 7, wherein the DC-DC converter operates in buck-boost mode.

9. A control module for a power management system adapted for use with a vehicle or marine electrical power system powered by an internal combustion engine and an alternator driven by the internal combustion engine, the power management system comprising a power control system comprising a DC-DC converter for converting power from the electrical power system, wherein the control module is configured to self-calibrate by performing steps of determining maximal current limits drawn from the alternator at respective discrete engine operating speeds by the control module for a predetermined voltage setpoint, the discrete engine operating speeds including an idle speed and at least one operating speed above idle speed; and generating a control strategy based upon controlling the current drawn from the alternator using an error signal based upon the difference between the alternator voltage and the predetermined voltage setpoint.

10. The control module of claim 9, wherein the control strategy is characterised by multiples operative modes that respectively draw differing levels of current from the alternator by varying the predetermined alternator voltage setpoint used in the control strategy.

11. The control module of claim 9, wherein the selected engine operating speeds define discrete control ranges to which discrete control strategies are applied.

12. The control module according to claim 11, wherein the control strategy comprises a proportional-integral-derivative (PID) control strategy.

13. The control module of claim 12, wherein the proportional-integral-derivative (PID) control strategy comprises respective sets of PID control parameters for the discrete control ranges.

14. The control module of claim 13, wherein the sets of PID control parameters for the discrete control ranges are different depending upon if the current drawn from the alternator is increasing or decreasing.

15. The control module of claim 14, wherein the DC-DC converter is bi-directional.

16. The control module of claim 15, wherein the DC-DC converter operates in buck-boost mode.

17. A power management system adapted for use with a vehicle or marine electrical power system powered by an internal combustion engine and an alternator driven by the internal combustion engine, the power management system comprising a power control system comprising a DC-DC converter for converting power from the electrical power system, a control module for controlling the DC-DC converter, wherein the control module is configured to self-calibrate the power management system following installation to the electrical power system by performing steps of determining maximal current loads drawn from the alternator at selected number of engine operating speeds and for a predetermined voltage setpoint, and generating a control strategy based upon controlling the current drawn from the alternator using an error signal based upon the difference between the alternator voltage and the predetermined voltage setpoint.

18. The power management system of claim 17, wherein the control strategy is characterised by multiples operative modes that respectively draw differing levels of current from the alternator by varying the predetermined alternator voltage setpoint used in the control strategy.

19. The power management system of claim 18, wherein the selected engine operating speeds define discrete control ranges to which discrete control strategies are applied.

20. The power management system of claim 19, wherein the control strategy comprises a proportional-integral-derivative (PID) control strategy, and the proportional-integral-derivative (PID) control strategy comprises respective sets of PID control parameters for the discrete control ranges, and wherein the sets of PID control parameters for the discrete control ranges are different depending upon if the current drawn from the alternator is increasing or decreasing.

21. (canceled)

22. (canceled)

23. (canceled)

24. (canceled)
